(19) United States
(12) Patent Application Publication
(10) Pub. No.: US 2025/0012986 A1
(43) Pub. Date: Jan. 9, 2025

(54) SUBSTRATE ASSEMBLY

(71) Applicant: FURUKAWA ELECTRIC CO., LTD., Tokyo (JP)

(72) Inventors: Yuta ISHIGE, Tokyo (JP); Kazuya NAGASHIMA, Tokyo (JP); Hideyuki NASU, Tokyo (JP)

(73) Assignee: FURUKAWA ELECTRIC CO., LTD., Tokyo (JP)

(21) Appl. No.: 18/891,051

(22) Filed: Sep. 20, 2024

Related U.S. Application Data
(63) Continuation of application No. PCT/JP2023/010728, filed on Mar. 17, 2023.

(30) Foreign Application Priority Data
Mar. 31, 2022 (JP) 2022-058989

(51) Int. Cl. G02B 6/42; H04B 10/40

(52) U.S. Cl. CPC G02B 6/4269; G02B 6/4245; H04B 10/40

(57) ABSTRACT

A substrate assembly includes: a substrate including a first surface facing a first direction, a second surface on a side opposite to the first surface, the second surface facing an opposite direction to the first direction, and an optical transceiver including a first electrical interface, and a heat dissipation portion, the optical transceiver being fixed to the substrate in a state where the first electrical interface and the heat dissipation portion face the opposite direction to the first direction and are aligned in a direction intersecting the first direction; and a first heat dissipation mechanism fixed to the substrate, the first heat dissipation mechanism including a first portion adjacent to the heat dissipation portion in the first direction and thermally connected with the heat dissipation portion in a state where the optical transceiver is fixed to the substrate.

This application is a continuation of International Application No. PCT/JP2023/010728, filed on Mar. 17, 2023 which claims the benefit of priority of the prior Japanese Patent Application No. 2022-058989, filed on Mar. 31, 2022, the entire contents of which are incorporated herein by reference.

### BACKGROUND

The present disclosure relates to a substrate assembly.

In the related art, small optical transceivers described in JP 2020-27147 A are known as optical transceivers used in a network switch device.

### SUMMARY

A network switch device that implements Co-Packaged Optics (CPO) includes a switch Application Specific Integrated Circuit (ASIC) and a plurality of optical transceivers mounted on a substrate.

As communication traffic increases, not only the heat generation amount of the switch ASIC, but also the heat generation amount of the optical transceivers tend to increase in this type of the network switch device. There is a need for an improved and novel substrate assembly that may more efficiently dissipate heat from optical transceivers as, for example, a substrate assembly including a substrate on which the optical transceivers are mounted.

According to one aspect of the present disclosure, there is provided a substrate assembly including: a substrate including a first surface facing a first direction, a second surface on a side opposite to the first surface, the second surface facing an opposite direction to the first direction, and an optical transceiver including a first electrical interface, and a heat dissipation portion, the optical transceiver being fixed to the substrate in a state where the first electrical interface and the heat dissipation portion face the opposite direction to the first direction and are aligned in a direction intersecting the first direction; and a first heat dissipation mechanism fixed to the substrate, the first heat dissipation mechanism including a first portion adjacent to the heat dissipation portion in the first direction and thermally connected with the heat dissipation portion in a state where the optical transceiver is fixed to the substrate.

### BRIEF DESCRIPTION OF THE DRAWINGS

FIG. 1 is an exemplary schematic perspective view of a switch device according to a first embodiment;

FIG. 2 is an exemplary schematic plan view of the switch device according to the first embodiment;

FIG. 3 is an exemplary schematic side view of part of the switch device according to the first embodiment;

FIG. 4 is a cross-sectional view taken along line IV-IV in FIG. 2;

FIG. 5 is an exemplary schematic plan view of part of the switch device according to the first embodiment, and is a view illustrating a state before optical transceivers are mounted, a state where the optical transceivers are mounted, and a state where the optical transceivers are attached;

FIG. 6 is an exemplary schematic cross-sectional view of part of a switch device according to a second embodiment;

FIG. 7 is an exemplary schematic cross-sectional view of part of a switch device according to a third embodiment;

FIG. 8 is an exemplary schematic cross-sectional view of part of a switch device according to a fourth embodiment;

FIG. 9 is an exemplary schematic perspective view of a switch device according to a fifth embodiment;

FIG. 10 is an exemplary schematic plan view of a switch device according to a fifth embodiment; and

FIG. 11 is an exemplary schematic side view of a switch device according to a fifth embodiment.

### DETAILED DESCRIPTION

Hereinafter, a plurality of exemplary embodiments will be disclosed. Configurations of the embodiments described below, and functions and results (effects) provided by the configurations are examples. The present disclosure may also be achieved by configurations other than configurations disclosed in the following embodiments. Furthermore, according to the present disclosure, it is possible to obtain at least one of various effects (including derivative effects, too) obtained by the configurations.

The plurality of embodiments described below have similar configurations. Hence, according to the configuration of each embodiment, it is possible to obtain similar functions and effects based on the similar configuration. Furthermore, similar reference numerals may be given to similar configurations, and redundant description may be omitted in the following description.

In each drawing, an arrow X indicates an X direction, an arrow Y indicates a Y direction, and an arrow Z indicates a Z direction. The X direction, the Y direction, and the Z direction intersect each other and are perpendicular to each other.

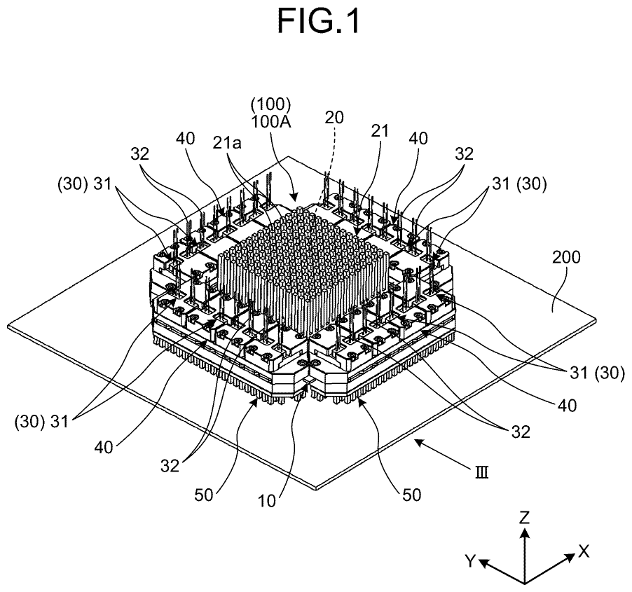

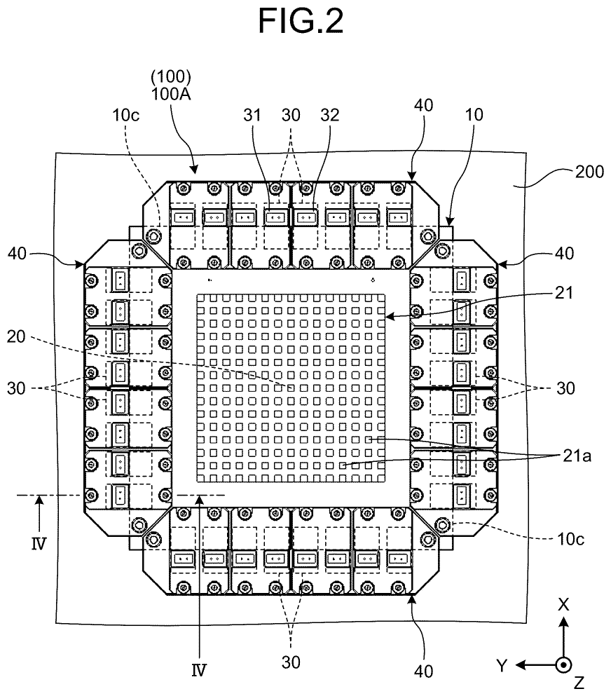

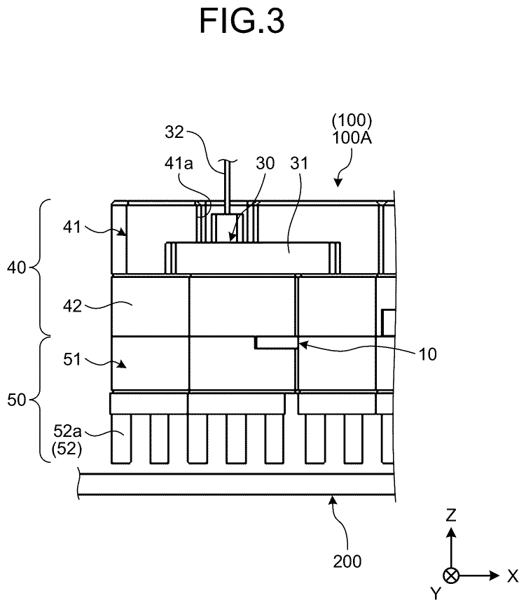

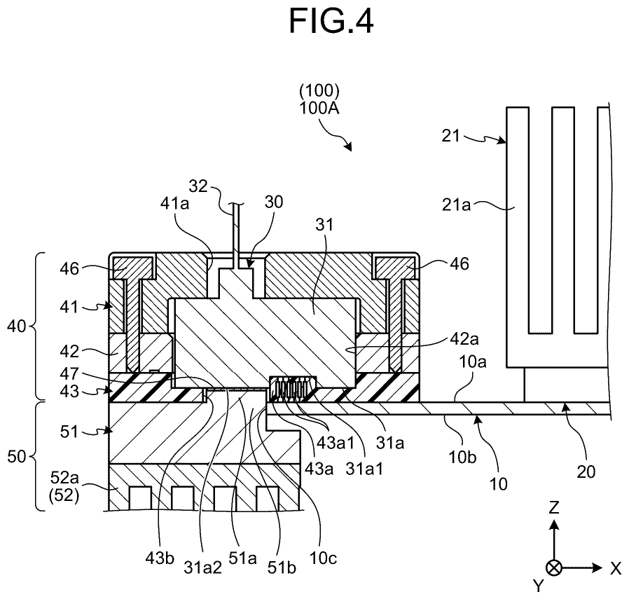

FIG. 1 is a perspective view of a switch device 100A (100) according to a first embodiment. FIG. 2 is a plan view of the switch device 100. FIG. 3 is a side view of part of the switch device 100 as viewed from an arrow III in FIG. 1 in the Y direction. Furthermore, FIG. 4 is a cross-sectional view taken along line IV-IV in FIG. 2.

As illustrated in FIG. 1, the switch device 100 is mounted on a motherboard 200. Note that, although only the one switch device 100 is mounted on the motherboard 200 in the present embodiment, a plurality of the switch devices 100 may be mounted on the motherboard 200. The motherboard 200 is an example of an integrated substrate.

As illustrated in FIGS. 1 and 2, the switch device 100 includes a substrate 10, a switch ASIC 20, a plurality of optical transceivers 30, a heat sink 21 for the switch ASIC 20, fixing mechanisms 40 for fixing the optical transceiver 30 to the substrate 10, and heat dissipation mechanisms 50 for the optical transceivers 30. The substrate 10, the fixing mechanisms 40, and the heat dissipation mechanisms 50 of the switch device 100 will be referred to as a substrate assembly. The substrate assembly is mountable on the motherboard 200.

As illustrated in FIG. 2, the substrate 10 has a square (quadrangular) shape. Furthermore, as illustrated in FIG. 4, the substrate 10 includes a surface 10a that intersects and expands perpendicularly to the Z direction, has a plate shape, and faces the Z direction, and a surface 10b that faces an opposite direction to the Z direction on a side opposite to the surface 10a. The surfaces 10a and 10b intersect and expand perpendicularly to the Z direction. The substrate 10 is, for example, a printed circuit board. The Z direction is an example of a first direction of the substrate 10, and may also be referred to as a thickness direction of the substrate 10.

Each optical transceiver 30 illustrated in FIGS. 1 to 4 receives an optical signal transmitted through an optical fiber 32 and outputs an electrical signal corresponding to the optical signal. The electrical signal output from the optical transceiver 30 is input to the switch ASIC 20 via conductors provided to a socket 43 (see FIG. 4) and the substrate 10. The optical transceiver 30 includes a photodiode array (not illustrated) as a plurality of light reception units that receive optical signals. Furthermore, each optical transceiver 30 receives an electrical signal from the switch ASIC 20 via conductors provided to the substrate 10 and the socket 43, and outputs an optical signal corresponding to the electrical signal. The optical signal output from the optical transceiver 30 is coupled to the optical fiber 32 and transmitted through the optical fiber 32. The optical transceiver 30 includes, for example, a VCSEL array (that is not illustrated and is a VCSEL: Vertical Cavity Surface Emitting Laser) as a plurality of light emitting units that output optical signals.

As illustrated in FIG. 2, the plurality of optical transceivers 30 are disposed along each side 10c of the substrate 10. Furthermore, in the present embodiment, as illustrated in FIG. 4, each optical transceiver 30 is mounted so as to cover the side 10c. In other words, each optical transceiver 30 is provided so as to cross the side 10c when viewed from the opposite side to the Z direction, and includes a portion located on an inner side of the side 10c and a portion located on an outer side of the side 10c. Consequently, it is possible to obtain advantages that it is easy to avoid an interference between the optical fibers 32 that extend from the optical transceivers 30 and other parts such as the switch ASIC 20 and the heat sink 21 mounted on the substrate 10, and it is possible to form the substrate 10 smaller.

Furthermore, as illustrated in FIGS. 1 and 2, the plurality of optical transceivers 30 are fixed to the substrate 10 by the fixing mechanism 40 provided per side 10c of the substrate 10. The fixing mechanism 40 is provided for each of the four sides 10c, that is, the four fixing mechanisms 40 are provided in total, and is shared between the plurality of (e.g., eight in the present embodiment) optical transceivers 30 disposed along each side 10c. As described above, by sharing the fixing mechanisms 40 between the plurality of optical transceivers 30, it is possible to further simplify the attachment structure of the fixing mechanisms 40 for the substrate 10 and further reduce the number of parts compared to a case where, for example, the optical transceivers 30 are fixed to the substrate 10 by each fixing mechanism, and, eventually, it is possible to obtain an advantage that it is possible to suppress labor and cost of manufacturing of the switch device 100.

As illustrated in FIGS. 1 and 2, the switch ASIC 20 is mounted on the substrate 10 at a position apart from each side 10c of the substrate 10 (e.g., a substantially center portion of the substrate 10 in the present embodiment). As illustrated in FIG. 4, for example, the switch ASIC 20 is flip-chip mounted on the surface 10a. The switch ASIC 20 controls an operation of each optical transceiver 30. The switch ASIC 20 is an example of a semiconductor integrated circuit.

As illustrated in FIG. 4, the heat sink 21 is provided in contact with the side of the switch ASIC 20 opposite to the substrate 10. The heat sink 21 is in contact with the top surface of the switch ASIC 20, and includes a plurality of fins 21a of an array shape and a pin shape that protrude from a base to the Z direction. Furthermore, the heat sink 21 is made of a material such as an aluminum-based metal material having relatively high thermal conductivity. According to this configuration, heat generated by the switch ASIC 20 transmits in the heat sink 21 in the Z direction, and is transferred, that is, dissipated to a gas around the fins 21a as a result of heat exchange between the fins 21a and the gas around the fins 21a. The heat sink 21 is an example of the second heat dissipation mechanism.

As illustrated in FIGS. 3 and 4, in the present embodiment, the fixing mechanism 40 includes an upper member 41, an intermediate member 42, and a socket 43. These components of the fixing mechanism 40 are integrated by a fixing tool 46 such as a screw. Furthermore, the intermediate member 42 and the socket 43 among the components of the fixing mechanism 40 are shared between all of the optical transceivers 30 of a group of the plurality of optical transceivers 30 along the side 10c of the substrate 10. As illustrated in FIG. 4, the fixing mechanism 40 fixes the optical transceivers 30 located near the side 10c of the substrate 10 to the substrate 10 in a state where the optical transceivers 30 are sandwiched in the thickness direction of the substrate 10.

Furthermore, to enable exchange after attachment of the optical transceivers 30, the fixing mechanism 40 detachably fix the optical transceivers 30 to the substrate 10. To achieve detachable fixing, in the present embodiment, the components of the fixing mechanism 40 include components that are fixed to the substrate 10, and components that are attachable to and detachable from the substrate 10. In the present embodiment, the intermediate member 42 and the socket 43 are fixed to the substrate 10, and the upper member 41 is configured to be attachable to and detachable from the intermediate member 42, that is, the substrate 10. More specifically, as illustrated in FIG. 4, the upper member 41 is attached to the intermediate member 42 by the fixing tool 46 formed as a detachable screw. The intermediate member 42 and the socket 43 are examples of first members, and the upper member 41 is an example of a second member.

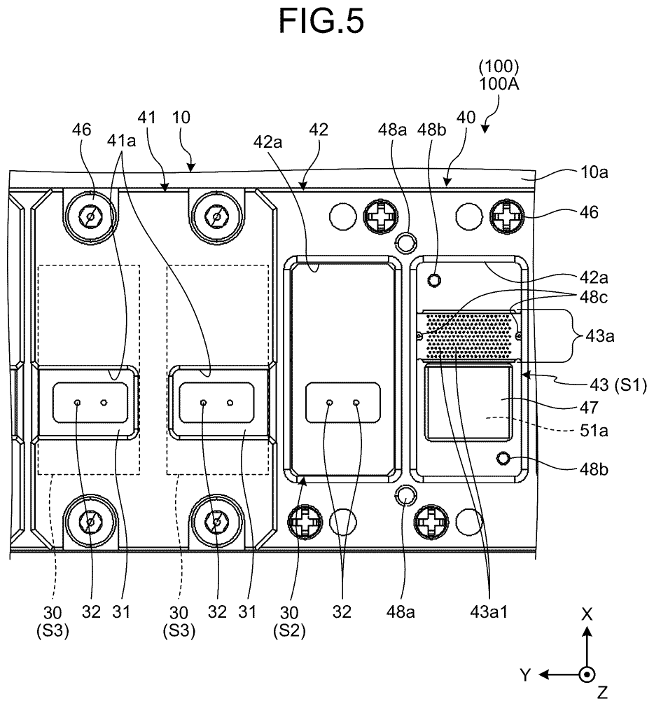

FIG. 5 is a plan view illustrating a state S1 before the optical transceivers 30 are mounted, a state S2 where the optical transceivers 30 are mounted, and a state S3 where the optical transceivers 30 are attached. In the present embodiment, as indicated by the state S3 in FIG. 5, the upper member 41 is shared between only the two adjacent optical transceivers 30 along the side 10c instead of being shared between all of the plurality of optical transceivers 30 along the side 10c. Consequently, it is possible to obtain advantages that it is possible to achieve, for example, both of facilitation of detachment of the individual optical transceivers 30 and common use of parts, and reduce influences of deflection of the fixing mechanisms 40 and manufacturing variations of the components of the fixing mechanisms 40, the optical transceivers 30, and the like, and further improve positioning accuracy. In this regard, these configurations are examples, and the upper member 41 may be shared between all of the plurality of optical transceivers 30 along the sides 10c.

The optical transceivers 30 includes a body 31 and a plurality of optical fibers 32. Note that a state where the optical transceivers 30 are fixed to the substrate 10 will be described in the following description unless otherwise specified.

As illustrated in FIG. 4, the body 31 includes a surface 31a that faces an opposite direction to the Z direction. The surface 31a is provided with an electrical interface 31al that is provided with an array of a plurality of electrodes (not illustrated), and a heat dissipation surface 31a2. In the fixed state, the electrical interface 31al and the heat dissipation surface 31a2 each face the opposite direction to the Z direction, and are aligned in a direction (the X direction of the optical transceivers 30 illustrated in FIG. 4) that lies substantially along the surface 10a of the substrate 10 and intersects the side 10c of the substrate 10. A heat generating body inside the optical transceiver 30 is aligned in the Z direction together with the heat dissipation surface 31a2. The electrical interface 31al is an example of a first electrical interface, and the heat dissipation surface 31a2 is an example of a heat dissipation portion.

The plurality of optical fibers 32 extend at portions apart from the surface 31a of the body 31, more specifically, on an opposite side to the heat dissipation surface 31a2, and from portions at which the optical fibers 32 are aligned in the Z direction together with the heat dissipation surface 31a2. Furthermore, the plurality of optical fibers 32 extend in the Z direction near the body 31 and from the body 31.

The socket 43, the intermediate member 42, and the upper member 41 are mounted in this order on the substrate 10.

The upper member 41 presses the body 31 of the optical transceiver 30 toward the substrate 10 and the socket 43 in the opposite direction to the Z direction. Furthermore, as illustrated in FIGS. 4 and 5, the upper member 41 is provided with an opening 41a that is a cutout that penetrates the upper member 41 in the Z direction. Part of the body 31 is housed in the opening 41a, and the optical fibers 32 extend through the opening 41a.

The intermediate member 42 is provided with an opening 42a that is a through-hole extending in the Z direction. The side surface of the opening 42a has a function of roughly guiding the body 31 of the optical transceiver 30 in the X direction and the Y direction when the body 31 is attached.

The socket 43 is mounted on the surface 10a of the substrate 10, and supports the body 31 of the optical transceiver 30. The socket 43 is provided with an electrical interface 43a and an opening 43b.

The electrical interface 43a includes conductors 43al that face the electrical interface 31al provided to the body 31 of the optical transceiver 30, and are electrically connected with each of a plurality of electrodes provided to the electrical interface 31al. The conductor 43al may be configured as a contact terminal that includes, for example, a pin that extends in the Z direction and may elastically extend and contract. The conductor 43al is electrically connected with the conductor (not illustrated) of the substrate 10. Each electrode of the electrical interface 31al of the optical transceiver 30 is electrically connected with conductors of the switch ASIC 20 via the conductors 43al of the electrical interface 43a of the socket 43 and the conductors of the substrate 10. By providing the socket 43 including the electrical interface 43a, it is possible to obtain an advantage that it is possible to more easily construct a configuration that may secure required positioning accuracy of a plurality of electrodes compared to a case where, for example, the electrical interface 43a is directly provided to the substrate 10. The electrical interface 43a is an example of a second electrical interface.

The opening 43b exposes the heat dissipation surface 31a2 provided to the body 31 of the optical transceiver 30 in the opposite direction to the Z direction. The opening 43b is provided as, for example, a through-hole or a cutout that penetrates the socket 43 in the Z direction.

The heat dissipation mechanism 50 dissipates heat generated by the optical transceivers 30. The heat dissipation mechanism 50 includes a lower member 51 and a heat sink 52. Note that at least the lower member 51 of the heat dissipation mechanism 50 may be configured to function as part of the fixing mechanism 40. The heat dissipation mechanism 50 is an example of a first heat dissipation mechanism.

The lower member 51 is located on an opposite side of the socket 43 to the intermediate member 42. The lower member 51 includes a portion 51a that is housed in the opening 43b, and a portion 51b that is aligned in a direction intersecting the substrate 10 in the Z direction. The lower member 51 is thermally connected with the heat dissipation surfaces 31a2 of the optical transceivers 30, and transfers heat generated by the optical transceivers 30. The lower member 51 is made of, for example, a material such as an aluminum-based metal material having relatively high thermal conductivity. Furthermore, the lower member 51 is fixed to the substrate 10 or the fixing mechanism 40 by a fixing tool such as a screw, an adhesive, or the like. The lower member 51 may be also referred to as a heat transfer member.

The portion 51a is adjacent to the heat dissipation surface 31a2 with a thermal conductive sheet 47 interposed therebetween, and is thermally connected with the heat dissipation surface 31a2. By providing the thermal conductive sheet 47, it is possible to obtain advantages that it is possible to suppress a gap produced between the heat dissipation surface 31a2 and the portion 51a from lowering heat conductive efficiency from the heat dissipation surface 31a2 to the portion 51a due to manufacturing variations, a difference between heat expansion coefficients between parts, or the like, and suppress an excessive pressing force from being produced between the heat dissipation surface 31a2 and the portion 51a.

The portion 51b is integrally provided with the portion 51a, and is thermally connected with the portion 51a. Furthermore, at a position at which the portion 51b is aligned in a direction (the X direction of the lower member 51 illustrated in FIG. 4) intersecting the substrate 10 in the Z direction, the portion 51b extends from the portion 51a to the opposite direction to the Z direction, that is, to the thickness direction of the substrate 10.

Furthermore, the lower member 51 is in contact with the heat sink 52 on a side of the substrate 10 opposite to the heat dissipation surface 31a2, and is thermally connected with the heat sink 52. The heat sink 52 includes a plurality of fins 52a of an array shape or a pin shape that protrude from the base to the opposite direction to the Z direction. Furthermore, the heat sink 52 is made of a material such as an aluminum-based metal material having relatively high heat conductivity. Furthermore, the heat sink 52 is fixed to the lower member 51 by a fixing tool such as a screw, soldering, an adhesive, or the like. Note that the lower member 51 and the heat sink 52 may be integrated as one member. The heat sink 52 may be also referred to as a heat transfer member or a heat dissipation member.

The lower member 51 and the heat sink 52 employing such configurations transfer heat generated by the optical transceivers 30 from the heat dissipation surface 31a2 to the opposite direction to the Z direction in the lower member 51 and the heat sink 52, and is transferred, that is, dissipated to a gas around the fins 52a as a result of heat exchange between the fins 52a and the gas around the fins 52a. Note that the switch device 100 includes an electrically driven fan, and may be configured such that an air current produced by an operation of the electrically driven fan to act on the heat sink 52.

Furthermore, as is clear from FIGS. 2, 4, and 5, the heat dissipation surface 31a2 is located on an opposite side of the electrical interface 31al to the switch ASIC 20. Such an arrangement provides advantages that it is possible to further shorten, for example, the lengths of the conductors between the electrical interface 31al and the switch ASIC 20, so that it easier to secure required transmission characteristics of an electrical signal, and may avoid an interference between the first heat dissipation mechanism and the conductors, so that it is possible to obtain required heat dissipation capability from the optical transceivers 30.

Furthermore, a positioning mechanism 48a illustrated in FIG. 5 positions the intermediate member 42 and the upper member 41 in a direction intersecting the Z direction. Positioning mechanisms 48b position the socket 43 and the optical transceivers 30 in the direction intersecting the Z direction. Furthermore, a positioning mechanism 48c positions the substrate 10 and the socket 43 in the direction intersecting the Z direction. The positioning mechanisms 48a to 48c are formed as members that are provided with, for example, pins and holes into which the pins are inserted. Furthermore, the positioning mechanisms 48a to 48c are provided at two portions apart from each other. The positioning mechanisms 48b at the two portions of these positioning mechanisms 48a to 48c are provided such that the electrical interface 43a is disposed between these positioning mechanisms 48b at the two portions. Consequently, it becomes easier to more accurately position the electrodes of the electrical interfaces 31al (see FIG. 4) of the optical transceivers 30 and the conductors 43al of the electrical interface 43a of the socket 43.

As described above, according to the present embodiment, it is possible to obtain an improved and novel substrate assembly that may efficiently dissipate heat generated by the optical transceivers 30 while avoiding an interference with the other parts using the heat dissipation mechanisms 50.

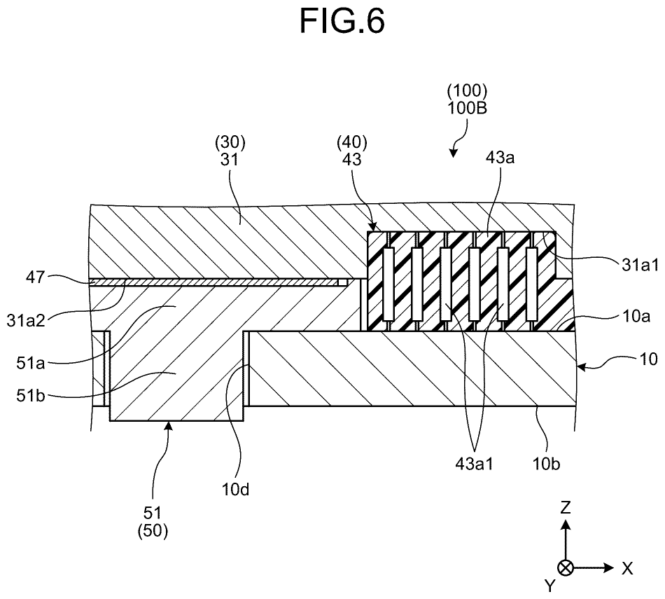

FIG. 6 is a cross-sectional view of part of a switch device 100B (100) according to a second embodiment at the same position as that in FIG. 4.

As illustrated in FIG. 6, in the present embodiment, a through-hole 10d that penetrates a substrate 10 in the Z direction is formed in the substrate 10, and a portion 51b penetrates the through-hole 10d in the Z direction. The portion 51b is an example of a third portion provided separately from the substrate 10. Note that, similarly to the above first embodiment, in the present embodiment, too, there may be provided a heat sink 52 that is adjacent to a lower member 51 in the opposite direction to the Z direction and is thermally connected with the lower member 51.

In the present embodiment, too, heat generated by the optical transceivers 30 transmits from the heat dissipation surface 31a2 to the opposite direction to the Z direction in the lower member 51, and is dissipated. According to the present embodiment, it is also possible to obtain a similar effect to that of the above first embodiment.

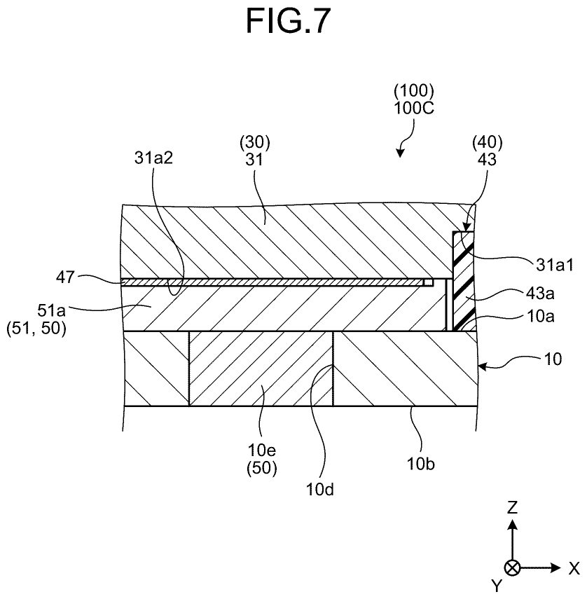

FIG. 7 is a cross-sectional view of part of a switch device 100C (100) according to a third embodiment at the same position as that in FIG. 4.

As illustrated in FIG. 7, in the present embodiment, a substrate 10 is provided with an inlay 10e that penetrates the substrate 10 in the Z direction. The inlay 10e is made of, for example, a material such as a copper-based metal material having relatively high heat conductivity. The inlay 10e is aligned in the Z direction in contact with a portion 51a of a lower member 51, and is thermally connected with the portion 51a. The inlay 10e forms part of the heat dissipation mechanism 50, and is an example of a third portion provided to the substrate 10. The inlay 10e may be also referred to as a heat transfer member or a heat dissipation member. Note that, in the present embodiment, too, there may be provided a heat sink 52 that is adjacent to the inlay 10e in the opposite direction to the Z direction and is thermally connected with the inlay 10e.

In the present embodiment, too, heat generated by the optical transceivers 30 is transferred from a heat dissipation surface 31a2 to the opposite direction to the Z direction in the lower member 51 and the inlay 10e, and is dissipated. According to the present embodiment, it is also possible to obtain a similar effect to that of the above first embodiment.

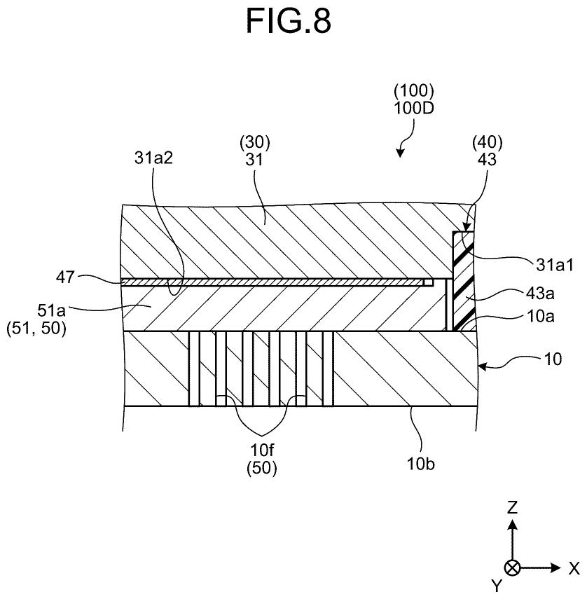

FIG. 8 is a cross-sectional view of part of a switch device 100D (100) according to a fourth embodiment at the same position as that in FIG. 4.

As illustrated in FIG. 8, in the present embodiment, a substrate 10 is provided with through vias 10f that penetrate the substrate 10 in the Z direction. The through via 10f is made of, for example, a material such as a copper-based metal material having relatively high heat conductivity. The through via 10f may be solid or may be hollow. In a case where the through via 10f is hollow, the through via 10f may be a plating layer. The through via 10f is aligned in the Z direction in contact with a portion 51a of a lower member 51, and is thermally connected with the portion 51a. The through vias 10f form part of a heat dissipation mechanism 50, and is an example of a third portion provided to the substrate 10. The through via 10f may be referred to as a heat transfer member or a heat dissipation member. Note that, in the present embodiment, too, there may be provided a heat sink 52 that is adjacent to the through vias 10f in the opposite direction to the Z direction and is thermally connected with the through vias 10f.

In the present embodiment, too, heat generated by the optical transceivers 30 is transferred from a heat dissipation surface 31a2 to the opposite direction to the Z direction in the lower member 51 and the through vias 10f, and dissipated. According to the present embodiment, it is also possible to obtain a similar effect to that of the above first embodiment.

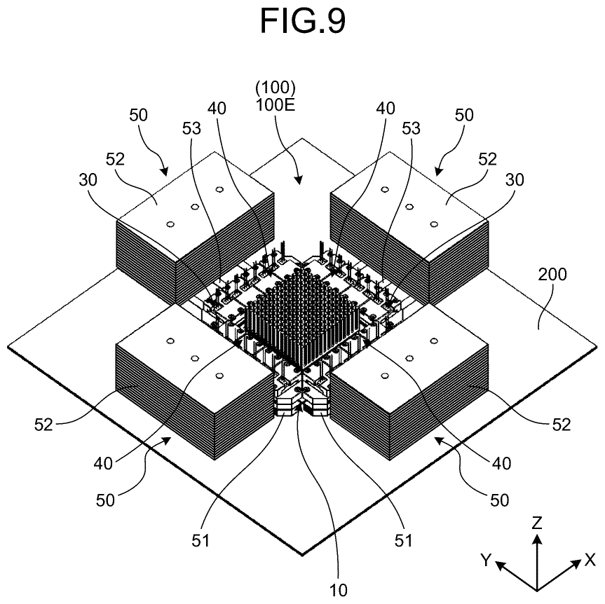

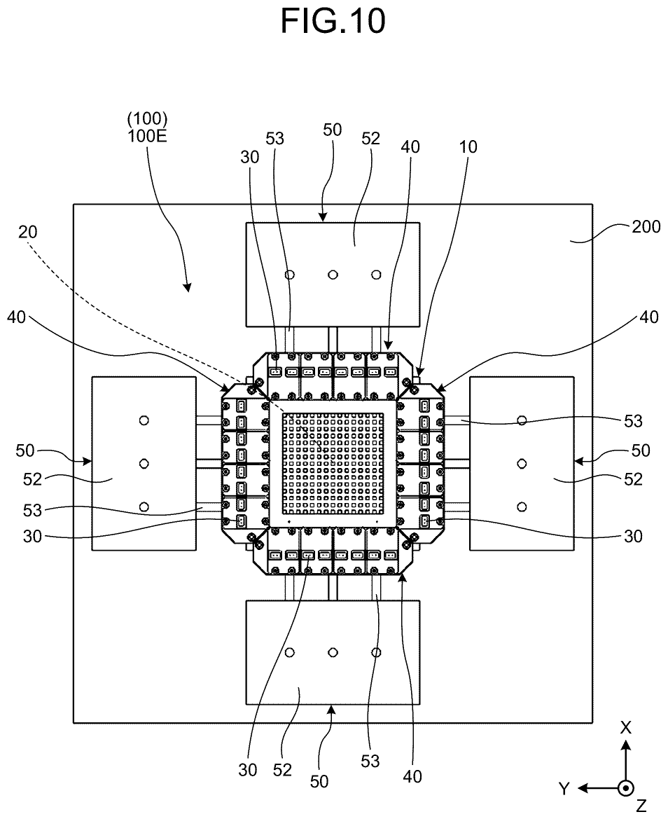

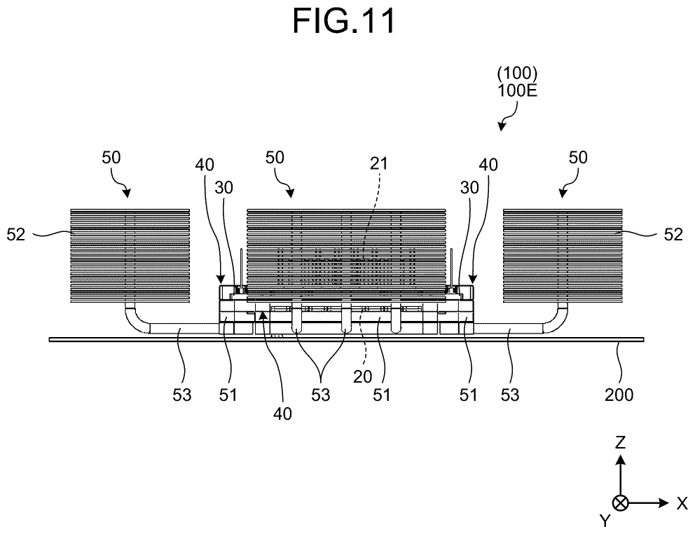

FIG. 9 is a perspective view of a switch device 100E (100) according to a fifth embodiment. FIG. 10 is a plan view of the switch device 100E (100). Furthermore, FIG. 11 is a side view of the switch device 100E (100).

As illustrated in FIGS. 9 to 11, in the present embodiment, a heat dissipation mechanism 50 includes a heat pipe 53 that is provided between a lower member 51 and a heat sink 52 and transports heat using a refrigerant. The heat pipe 53 transports heat from the lower member 51 to the heat sink 52 in a state where the refrigerant has been heated at the lower member 51 and become a gas, is cooled by the heat sink 52 to a liquid, and returns to the lower member 51. The heat pipe 53 is an example of a heat transport mechanism.

By providing the heat pipes 53, it is possible to obtain advantages that it is possible to dissipate heat from, for example, a place at which heat may be more easily dissipated, and eventually more efficiently cool optical transceivers 30.

Note that the heat pipes 53 may be thermally connected with the heat sink 52 of a switch ASIC 20. In this case, the heat sink 52 may be shared between the switch ASIC 20 and the optical transceivers 30, and consequently the number of parts may be reduced, so that it is possible to obtain an advantage that it is possible to reduce, for example, labor and cost of manufacturing.

Although the embodiments have been exemplified above, the above embodiments are examples, and do not intend to limit the claims. The above embodiments may be carried out as other various aspects, and may be variously omitted, replaced, combined, and changed without departing from the gist of the disclosure. Furthermore, specifications such as each configuration and each shape (such as structures, types, directions, models, sizes, lengths, widths, thicknesses, heights, numbers, arrangement, positions, and materials) may be changed as appropriate and implemented.

The present disclosure may be used for a substrate assembly.

According to the present disclosure, it is possible to obtain, for example, an improved and novel substrate assembly that may more efficiently dissipate heat from optical transceivers.

Although the disclosure has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A substrate assembly comprising:
a substrate including
a first surface facing a first direction,
a second surface on a side opposite to the first surface, the second surface facing an opposite direction to the first direction, and
an optical transceiver including a first electrical interface, and a heat dissipation portion, the optical transceiver being fixed to the substrate in a state where the first electrical interface and the heat dissipation portion face the opposite direction to the first direction and are aligned in a direction intersecting the first direction; and
a first heat dissipation mechanism fixed to the substrate, the first heat dissipation mechanism including a first portion adjacent to the heat dissipation portion in the first direction and thermally connected with the heat dissipation portion in a state where the optical transceiver is fixed to the substrate.

2. The substrate assembly according to claim 1, wherein
the optical transceiver includes a body fixed to the substrate, the body including the first portion, and
a plurality of optical fibers extend from a side of the body opposite to the heat dissipation portion.

3. The substrate assembly according to claim 1, wherein the first heat dissipation mechanism includes a second portion that is adjacent to the first portion and aligned in a direction intersecting the substrate in the first direction.

4. The substrate assembly according to claim 1, wherein the first heat dissipation mechanism includes a third portion that is adjacent to the first portion and penetrates the substrate in the first direction.

5. The substrate assembly according to claim 4, wherein the third portion is provided on the substrate.

6. The substrate assembly according to claim 4, wherein the third portion is provided separately from the substrate.

7. The substrate assembly according to claim 1, wherein the first heat dissipation mechanism includes a heat transport mechanism configured to transport heat using a refrigerant.

8. The substrate assembly according to claim 1, wherein the first heat dissipation mechanism includes a heat sink.

9. The substrate assembly according to claim 1, further comprising a semiconductor integrated circuit mounted on the first surface.

10. The substrate assembly according to claim 9, wherein the semiconductor integrated circuit includes a second heat dissipation mechanism on a side opposite to the substrate in a state where the semiconductor integrated circuit is mounted on the substrate.

11. The substrate assembly according to claim 9, wherein the optical transceiver is fixed to the substrate in a state where the heat dissipation portion is located on a side of the first electrical interface opposite to the semiconductor integrated circuit.

12. The substrate assembly according to claim 1, wherein a plurality of optical transceivers are fixed to the substrate as the optical transceiver.

13. The substrate assembly according to claim 12, wherein the plurality of optical transceivers are disposed along a side of the substrate.

14. The substrate assembly according to claim 13, wherein
the plurality of optical transceivers are disposed along four sides of the substrate, and
a semiconductor integrated circuit is mounted at a position on the first surface apart from each of the sides than the optical transceiver.

15. The substrate assembly according to claim 1, further comprising a fixing mechanism configured to fix the optical transceiver to the substrate.

16. The substrate assembly according to claim 15, wherein the fixing mechanism is shared between a plurality of optical transceivers that function as the optical transceiver.

17. The substrate assembly according to claim 15, wherein the fixing mechanism is configured to detachably fix the optical transceiver to the substrate.

18. The substrate assembly according to claim 17, wherein the fixing mechanism includes:
a first member fixed to the substrate; and
a second member detachably fixed to the first member and configured to press the optical transceiver toward the substrate.

19. The substrate assembly according to claim 18, wherein
the optical transceiver includes a body fixed to the substrate, the body including the first portion,
a plurality of optical fibers extend from a side of the body opposite to the heat dissipation portion, and
the second member includes an opening through which the optical fiber passes.

20. The substrate assembly according to claim 1, further comprising:
a second electrical interface fixed to the substrate and electrically connected with the first electrical interface; and
a positioning mechanism configured to position the first electrical interface and the second electrical interface.

21. The substrate assembly according to claim 1, further comprising a socket attached to the substrate, the socket including a second electrical interface electrically connected with the first electrical interface.

22. The substrate assembly according to claim 1, further comprising a heat conductive member having flexibility, the heat conductive member being provided between the first portion and the heat dissipation portion.

23. An integrated substrate for mounting a plurality of substrate assemblies, comprising
the substrate assembly according to claim 1.
